(19) United States
(12) Patent Application Publication
(10) Pub. No.: US 2026/0334003 A1
(43) Pub. Date: Oct. 22, 2026

(54) DISPLAY PANEL

(71) Applicant: Wuhan China Star Optoelectronics Technology Co., Ltd., Wuhan, Hubei (CN)

(72) Inventors: Zhifu LI, Wuhan, Hubei (CN); Jianfeng YUAN, Wuhan, Hubei (CN); Fei AI, Wuhan, Hubei (CN); Dewei SONG, Wuhan, Hubei (CN); Chengzhi LUO, Wuhan, Hubei (CN)

(21) Appl. No.: 18/578,340

(22) PCT Filed: Dec. 13, 2023
(86) PCT No.: PCT/CN2023/138412

§ 371 Date: Jan. 11, 2024

(30) Foreign Application Priority Data
Dec. 1, 2023 (CN) 202311650891.0

(51) Int. Cl. H10K 59/121; H10K 59/123

(52) U.S. Cl. CPC H10K 59/1213; H10K 59/123

(57) ABSTRACT

A display panel is provided. A first active layer includes a first channel and a first drain ohmic contact portion. A separation portion covers the first channel. A first drain includes a transparent first portion and a transparent second portion. The first portion is disposed on a surface of a side of the separation portion which is away from the first active layer. The second portion is disposed on the first drain ohmic contact portion. A pixel electrode is electrically connected to the first portion through a first via provided on a side of the first portion which is away from the separation portion.

### TECHNICAL FIELD

The present application relates to the field of display technologies, and more particularly, to a display panel.

### BACKGROUND

With the development of display technology, consumer electronic products such as a mobile phone, a television, a personal digital assistant, a digital camera, a notebook computer, a desktop computer, a Virtual Reality (referred briefly to as VR) display device, and an Augmented Reality (referred briefly to as AR) display device, which rely on a display function of a display panel, are constantly emerging. The rise of the concept of ‘metaverse space’ also causes the VR/AR display device to be widely concerned by consumers and to have a broad market application prospect.

The VR/AR display device is a near-eye display device. There is a high requirement for an aperture ratio and a display image quality of a display panel therein, and there is a need to reduce manufacturing costs as much as possible. The display panel includes a pixel electrode and a thin film transistor (referred briefly to as TFT) electrically connected to the pixel electrode. The thin film transistor is a switching element that controls the pixel electrode to acquire a pixel voltage. A connection manner of the thin film transistor and the pixel electrode, and a structure of the thin film transistor directly affect an aperture ratio, a display image quality, and production costs of the display panel.

Therefore, there are problems urgently to be solved by a person skilled in the art how to provide a structure of thin film transistors electrically connected to pixel electrodes and a connection manner between the thin film transistors and the pixel electrodes so that a display panel has a high aperture ratio, a high display image quality, and a low production and manufacturing cost.

### SUMMARY

The present application provides a display panel, which can effectively solve the problem that the display panel has a high aperture ratio while the display image quality and the manufacturing cost are not considered.

A display panel is provided by the present application, and includes a display region. The display panel includes: a substrate; first thin film transistors disposed on one side of the substrate and located in the display region; pixel electrodes, each of the pixel electrodes being disposed on a side of a corresponding one of the first thin film transistors which is away from the substrate and being located in the display region; in which each of the first thin film transistors includes: a first active layer including a first channel and a first drain ohmic contact portion provided on a side of the first channel; a separation portion disposed on a surface of one side of the first channel which is away from the substrate and covering the first channel; a first drain including a transparent first portion disposed on a surface of a side of the separation portion which is away from the first active layer and a transparent second portion disposed on a surface of a side of the first drain ohmic contact portion which is away from the substrate; in which a corresponding one of the pixel electrodes is electrically connected to the first portion through a first via provided on a side of the first portion which is away from the separation portion.

### BRIEF DESCRIPTION OF THE DRAWINGS

In order that the technical solution in the embodiments of the present application may be explained more clearly, reference will now be made briefly to the accompanying drawings required for the description of the embodiments. It will be apparent that the accompanying drawings in the following description are merely some of the embodiments of the present application, and other drawings may be made to those skilled in the art without involving any inventive effort.

FIG. 1 is a schematic plan view of a display panel in the related art.

FIG. 2 is a schematic sectional view of a display panel in the related art.

FIG. 3 is a schematic plan view of a display panel according to some embodiments of the present application.

FIG. 4 is a schematic sectional view of a display panel according to some embodiments of the present application.

FIG. 5a is a schematic sectional view of a separation portion, with an included angle of 90 degrees between a side wall of the separation portion and a bottom surface of the separation portion according to some embodiments of the present application.

FIG. 5b is a schematic sectional view of a separation portion, with an included angle of 30 degrees between a side wall of the separation portion and a bottom surface of the separation portion according to some embodiments of the present application.

FIG. 6a is a schematic structural diagram of a display panel corresponding to step S01 in a method for manufacturing a display panel according to embodiments of the present application.

FIG. 6b is a schematic structural diagram of a display panel corresponding to step S02 in a method for manufacturing a display panel according to embodiments of the present application.

FIG. 6c is a schematic structural diagram of a display panel corresponding to step S03 in a method for manufacturing a display panel according to embodiments of the present application.

FIG. 6d is a schematic structural diagram of a display panel corresponding to step S04 in a method for manufacturing a display panel according to embodiments of the present application.

FIG. 6e is a schematic structural diagram of a display panel corresponding to step S05 in a method for manufacturing a display panel according to embodiments of the present application.

FIG. 6f is a schematic structural diagram of a display panel corresponding to step S06 in a method for manufacturing a display panel according to embodiments of the present application.

FIG. 6g is a schematic structural diagram of a display panel corresponding to step S07 in a method for manufacturing a display panel according to embodiments of the present application.

FIG. 6h is a schematic structural diagram of a display panel corresponding to step S08 in a method for manufacturing a display panel according to embodiments of the present application.

FIG. 6i is a schematic structural diagram of a display panel corresponding to step S09 in a method for manufacturing a display panel according to embodiments of the present application.

FIG. 6j is a schematic structural diagram of a display panel corresponding to step S10 in a method for manufacturing a display panel according to embodiments of the present application.

FIG. 6k is a schematic structural diagram of a display panel corresponding to step S11 in a method for manufacturing a display panel according to embodiments of the present application.

### LIST OF THE REFERENCE CHARACTERS

display region AA′; non-display region NAA′; substrate 10′; thin film transistor 20′; active layer 21′; channel 211′; drain ohmic contact portion 212′; first gate 22′; second gate 23′; source 24′; drain 25′; pixel electrode 30′; first via 40′; second via 50′;
display region AA; non-display region NAA; substrate 10; first thin film transistor 20; first active layer 21; first channel 211; first drain ohmic contact portion 212; first source ohmic contact portion 213; separation portion 22; side wall 221 of the separation portion; bottom surface 222 of the separation portion; edge 223 of the separation portion; first drain 23; first portion 231; edge 2311 of the first portion; second portion 232; first source 24; first gate 25; pixel electrode 30; first via 40; first gate insulating layer 50; first sub-insulating layer 51; second sub-insulating layer 52; second thin film transistor 60; second active layer 61; second gate 62; second source 63; second drain 64; first source conducting portion 70; second via 80; second gate insulating layer 90; composite functional layer 100; interlayer dielectric layer 110; first planarization layer 120; passivation layer 130; second planarization layer 140; and common electrode 150.

### DETAILED DESCRIPTION

A display panel is provided by the present application, and includes a display region. The display panel includes: a substrate; first thin film transistors disposed on one side of the substrate and located in the display region; pixel electrodes, each of the pixel electrodes being disposed on a side of a corresponding one of the first thin film transistors which is away from the substrate and being located in the display region; in which each of the first thin film transistors includes: a first active layer including a first channel and a first drain ohmic contact portion provided on a side of the first channel; a separation portion disposed on a surface of one side of the first channel which is away from the substrate and covering the first channel; a first drain including a transparent first portion disposed on a surface of a side of the separation portion which is away from the first active layer and a transparent second portion disposed on a surface of a side of the first drain ohmic contact portion which is away from the substrate; in which a corresponding one of the pixel electrodes is electrically connected to the first portion through a first via provided on a side of the first portion which is away from the separation portion.

Optionally, the second portion covers the first drain ohmic contact portion.

Optionally, the second portion covers a side wall of the separation portion, and an included angle between the side wall of the separation portion and a bottom surface of the separation portion is denoted by a, a range of which is denoted by 30°≤a≤90°.

Optionally, an edge of the separation portion protrudes from an edge of the first portion in a direction in which the separation portion is away from the second portion.

Optionally, the first active layer further includes a first source ohmic contact portion provided on an other side of the first channel; the first thin film transistor further includes a first source integrally formed with the first drain, and the first source is provided on a surface of a side of the first source ohmic contact portion which is away from the substrate, and covers the first source ohmic contact portion.

Optionally, the display panel further includes a first gate insulating layer disposed on a side of the first active layer which is away from the separation portion, in which the first gate insulating layer includes a first sub-insulating layer, the first sub-insulating layer is in contact with the first active layer, and the first sub-insulating layer is of a same material as the separation portion.

Optionally, the display panel further includes second thin film transistors disposed on a side of the substrate which faces towards the first thin film transistors, each of the second thin film transistor includes a second active layer disposed on a side of the first active layer which is away from the separation portion, and the second active layer includes a second channel having a different material from the first channel.

Optionally, the first gate insulating layer further includes a second sub-insulating layer disposed on a side of the first sub-insulating layer which is away from the first active layer, and the second sub-insulating layer and the first sub-insulating layer are different in material; the first thin film transistor includes a first gate disposed on a side of the second sub-insulating layer which is away from the first sub-insulating layer; the second thin film transistor further includes a second gate disposed on a side of the second active layer which is away from the substrate; in which the first gate is provided in a same layer as the second gate, and the first gate and the second gate are respectively in contact with the second sub-insulating layer.

Optionally, the display panel further includes a second gate insulating layer disposed on a side of the second active layer which faces towards the second gate, in which the first gate insulating layer disposed between the first active layer and the first gate has a first thickness, the second gate insulating layer disposed between the second active layer and the second gate has a second thickness, and a ratio of the first thickness to the second thickness is less than or equal to 3.

Optionally, the second thin film transistor further includes a second source and a second drain, the first thin film transistor further includes a first source conducting portion provided in a same layer as the second source and the second drain, and the first source conducting portion is electrically connected to the first source through a second via.

A display panel is provided by the present application, and includes a display region. The display panel includes: a substrate; first thin film transistors disposed on one side of the substrate and located in the display region; pixel electrodes, each of the pixel electrodes being disposed on a side of a corresponding one of the first thin film transistors which is away from the substrate and being located in the display region; in which each of the first thin film transistors includes: a first active layer including a first channel and a first drain ohmic contact portion provided on a side of the first channel; a separation portion disposed on a surface of one side of the first channel which is away from the substrate and covering the first channel; a first drain including a transparent first portion disposed on a surface of a side of the separation portion which is away from the first active layer and a transparent second portion disposed on a surface of a side of the first drain ohmic contact portion which is away from the substrate; in which a corresponding one of the pixel electrodes is electrically connected to the first portion through a first via provided on a side of the first portion which is away from the separation portion. The display panel provided in the present application can improve the display image quality of the display panel and reduce the manufacturing cost of the display panel while achieving a high aperture ratio.

The embodiments of the above technical solutions are described in detail below with reference to the accompanying drawings.

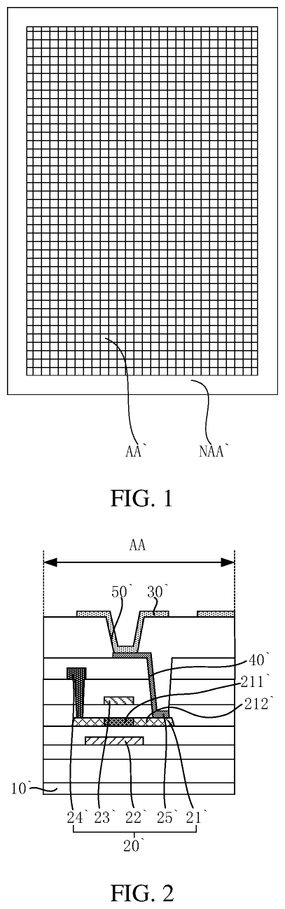

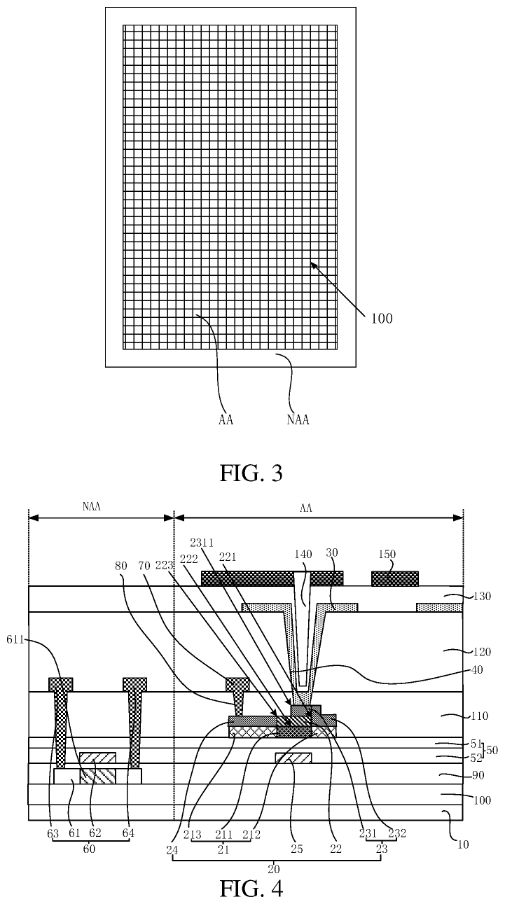

FIG. 1 is a schematic plan view of a display panel in the related art; and FIG. 2 is a schematic sectional view of a display panel in the related art. As shown in FIGS. 1 and 2, in the related art, a display panel 100′ includes a display region AA′ and a non-display region NAA′, as well as includes a substrate 10′, thin film transistors 20′ disposed on one side of the substrate 10′, and pixel electrodes 30′ disposed on one side of the thin film transistors 20′ which is away from the substrate 10′. Each of the thin film transistor 20′ and the pixel electrode 30′ is located in the display region AA′ of the display panel 100′. The thin film transistor 20′ includes an active layer 21′, a first gate 22′, a second gate 23′, a source 24′, and a drain 25′. The active layer 21′ includes a channel 211′ and a drain ohmic contact portion 212 disposed on one side of the channel 211′. The drain 25′ is lapped on the drain ohmic contact portion 212′ through a first via 40′, and the pixel electrode 30′ is lapped on the drain 25′ through a second via 50′. Since the drain 25′ is made of a transparent conductive material, a region of the drain 25′ which is lapped with the drain ohmic contact portion 212′ can be made to have high light transmittance for performing a display function, thereby improving the aperature ratio of the display panel 100. However, the first via 40′is formed in the region of the drain 25′ which is lapped with the drain ohmic contact portion 212′. So, for such a via structure, e.g., the first via 40′, when the display function is executed in the region where this via structure is, the phenomenon of the nonuniform display is caused, and further the display quality of the display panel 100′ is reduced. The first via 40′ and the second via 50′ increase the processing steps of the display panel 100′, thereby increasing the manufacturing cost of the display panel 1001.

The present application provides a display panel and a manufacturing method thereof in order to enable a display panel to achieve a high aperture ratio while improving the display image quality and reducing the manufacturing costs.

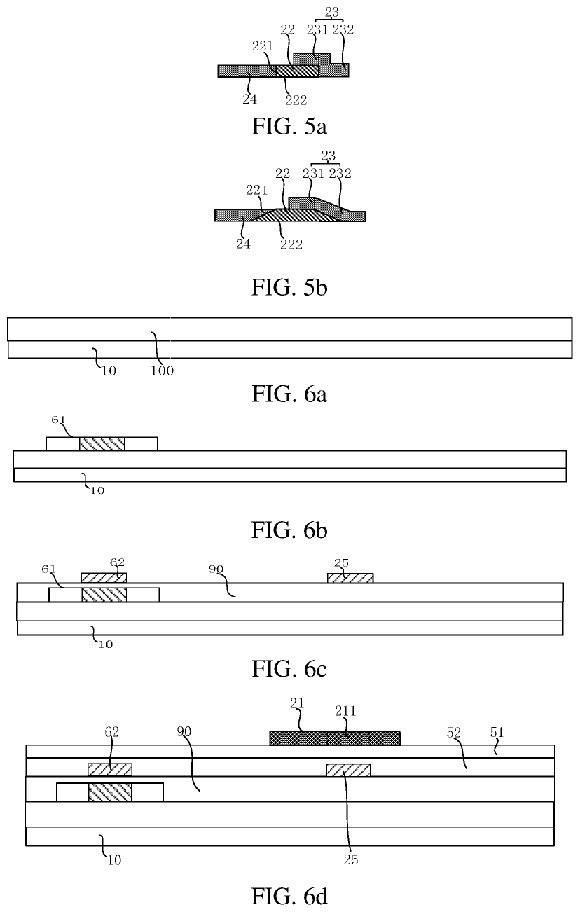

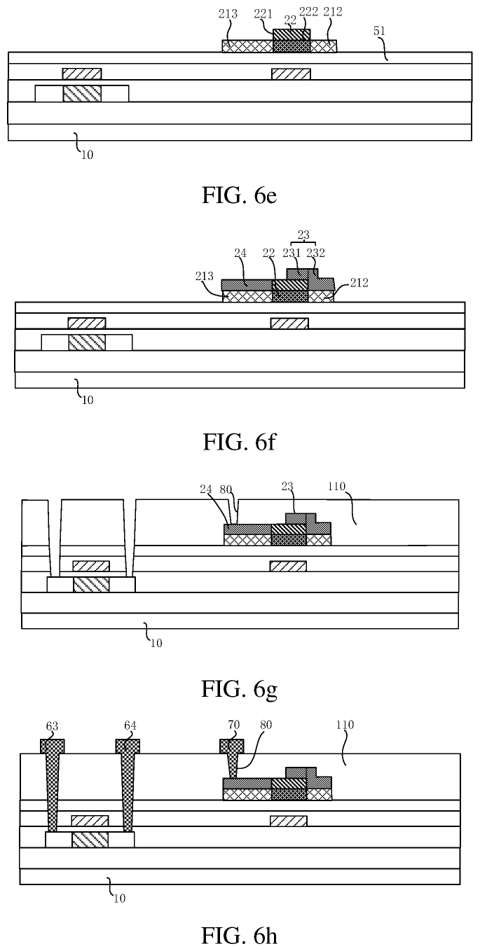

FIG. 3 is a schematic plan view of a display panel according to some embodiments of the present application; FIG. 4 is a schematic sectional view of a display panel according to some embodiments of the present application. As shown in FIGS. 3 and 4, in a first aspect, an embodiment of the present application provides a display panel having a display region AA and a non-display region NAA. The non-display region NAA surrounds the display region AA. The display region AA is provided with multiple display pixels in an array. The display panel includes a substrate 10, first thin film transistors 20 provided on one side of the substrate 10 and located in the display region AA, and pixel electrodes 30. The pixel electrode 30 is disposed on one side of the first thin film transistor 20 which is away from the substrate 10 and located in the display region AA.

In some embodiments of the present application, the first thin film transistor 20 includes: a first active layer 21 including a first channel 211 and a first drain ohmic contact portion 212 provided on a side of the first channel 211; a separation portion 22 disposed on a surface of one side of the first channel 211 which is away from the substrate 10 and covering the first channel 211; a first drain 23 including a transparent first portion 231 disposed on a surface of a side of the separation portion 22 which is away from the first active layer 21 and a transparent second portion 232 disposed on a surface of a side of the first drain ohmic contact portion 212 which is away from the substrate 10. The pixel electrode 30 is electrically connected to the first portion 231 through a first via 40 provided on a side of the first portion 231 which is away from the separation portion 22.

In the display panel provided in the present application, since the second portion 232 provided on the surface of the side of the first drain ohmic contact portion 212 which is away from the substrate 10 is transparent, the region in which the first drain ohmic contact portion 212 is provided can be made to have high light transmittance for performing a display function, thereby improving the aperture ratio of the display panel.

Further, the pixel electrode 30 is electrically connected to the first portion 231 through the first via 40 provided on the side of the first portion 231 which is away from the separation portion 22. And, the first portion 231 is provided on the separation portion 22 corresponding to the first channel 211. That is, in a direction perpendicular to the substrate 10, the first via 40 and the first drain ohmic contact portion 212 are provided in a misalignment manner. Thus, the first via 40 does not affect the display function of the region in which the first drain ohmic contact portion 212 is provided.

In addition, the first portion 231 is provided on the surface of the side of the separation portion 22 which is away from the first active layer 21. And, the second portion 232 is provided on the surface of the side of the first drain ohmic contact portion 212 which is away from the substrate 10. That is, in the direction perpendicular to the substrate 10, the first portion 231 and the second portion 232 are separated by only one separation portion 22. Thus, the first portion 231 and the second portion 232 are integrally formed without being connected by a via structure, so that the via structure is not required above the second portion 232. In this way, the region in which the first drain ohmic contact portion 212 is located has a consistent display effect with other display regions AA, the display uniformity of the display panel is improved, and the display quality of the display panel is improved.

In some embodiments of the present application, the vertical projection of the first via 40 on the first active layer 21 overlaps the first channel 211.

In the display panel provided in the present application, a channel region of the thin film transistor is usually provided with an non-transparent gate. That is, the display panel does not have a display function in the channel region of the thin film transistor. By overlapping the vertical projection of the first via 40 on the first active layer 21 with the first channel 211 in the present application, the first via 40 can be prevented from occupying an region with a display function in the display region AA, so that the aperture ratio of the display panel can be further improved.

In some embodiments of the present application, the first thin film transistor 20 is a metal oxide thin film transistor, the material of the first channel 211 is a metal oxide semiconductor, and the first drain ohmic contact portion 212 is a transparent conductive structure formed by conducting a metal oxide semiconductor material. Thus, the display panel can have the advantages of low leakage current, low refresh rate, and high light transmittance.

In some embodiments of the present application, the second portion 232 covers the drain ohmic contact portion. Optionally, the edge of the second portion 232 protrudes from the edge of the drain ohmic contact portion by 0.5 to 1 microns.

In the display panel provided in the present application, since the second portion 232 covers the first drain ohmic contact portion 212, the second portion 232 can protect the first drain ohmic contact portion 212 to avoid the damage to the first drain ohmic contact portion 212 during the patterning of the film layer in which the first drain 23 is located.

In some embodiments of the present application, the second portion 232 covers a side wall 221 of the separation portion 22, and an included angle between the side wall 221 of the separation portion 22 and a bottom surface 222 of the separation portion 22 is denoted by a, a range of which is denoted by 30°≤a≤90°.

In the display panel provided in the present application, an end of the second portion 232 which is adjacent to the first portion 231 covers the side wall 221 of the separation portion 22, and is connected to the first portion 231. Therefore, a step structure corresponding to the shape of the side wall 221 of the separation portion 22 is formed at the junction of the first portion 231 and the second portion 232. When the angle between the side wall 221 of the separation portion 22 and the bottom surface 222 of the separation portion 22 is too large, such as an obtuse angle, an undercut structure is formed between the side wall 221 of the separation portion 22 and the first active layer 21, thereby greatly increasing the risk of fracture at the junction of the first portion 231 and the second portion 232. When the angle between the side wall 221 of the separation portion 22 and the bottom surface 222 of the separation portion 22 is too small, for example, less than 30 degrees, the area of the top surface of the separation portion 22 is reduced, thereby reducing the area of the first portion 231. Further, the electrical connection stability of the first drain 23 and the pixel electrode 30 is affected. By controlling the included angle between the side wall 221 of the separation portion 22 and the bottom surface 222 of the separation portion 22 to be in the range of 30 degrees to 90 degrees, the application can reduce the risk of fracture at the junction of the first portion 231 and the second portion 232, and make the top surface of the separation portion 22 and the first portion 231 have a larger area, thereby improving the electrical connection stability of the first drain 23 and the pixel electrode 30, and reducing the design difficulty of the first via 40.

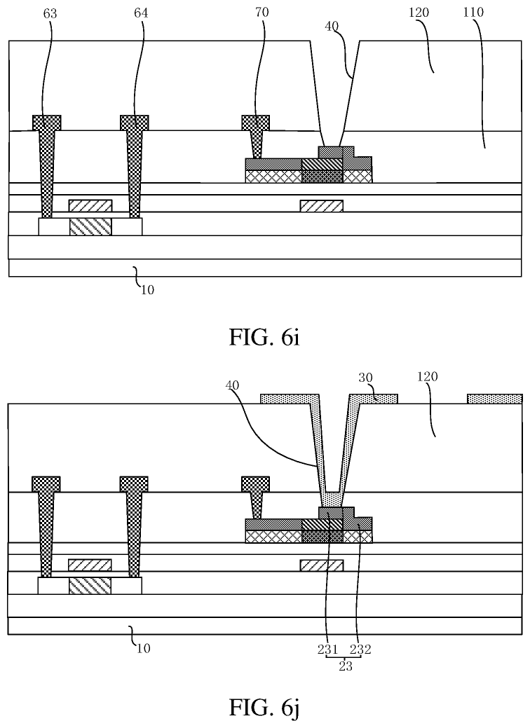

FIG. 5a is a schematic sectional view of a separation portion, with an included angle of 90 degrees between a side wall of the separation portion and a bottom surface of the separation portion according to some embodiments of the present application. As shown in FIG. 4 and FIG. 5a, the included angle between the side wall 221 of the separation portion 22 and the bottom surface 222 of the separation portion 22 is 90 degrees, which makes it possible to increase the area of the top surface of the separation portion 22 and the area of the first portion 231 as much as possible while reducing the risk of fracture at the junction of the first portion 231 and the second portion 232 and reducing the area of the bottom surface of the separation portion 22. Further, the design difficulty of the first via 40 is reduced.

FIG. 5b is a schematic sectional view of a separation portion, with an included angle of 30 degrees between a side wall of the separation portion and a bottom surface of the separation portion according to some embodiments of the present application. As shown in FIG. 4 and FIG. 5b, the included angle between the side wall 221 of the separation portion 22 and the bottom surface 222 of the separation portion 22 is 30 degrees, so that the risk of fracture at the junction of the first portion 231 and the second portion 232 can be reduced as much as possible while satisfying requirements for both the area of the top surface of the separation portion 22 and the area of the first portion 231 and the electrical connection stability of the first drain 23 and the pixel 30, thereby improving the stability of the first drain 23 electrically connecting the pixel electrode 30 and the first drain ohmic contact portion 212.

In some embodiments of the present application, an edge of the separation portion 22 protrudes from an edge 2311 of the first portion 231 in a direction in which the separation portion 22 is away from the second portion 232. Alternatively, the edge 223 of the separation portion 22 protrudes from the edge 2311 of the first portion 231 by 1 to 2 microns.

In the display panel provided in the present application, since the edge 223 of the separation portion 22 protrudes from the edge 2311 of the first portion 231 in the direction in which the separation portion 22 is away from the second portion 232, it is possible to ensure that the first portion 231 does not extend beyond the edge 223 of the separation portion 22, thereby avoiding the shorting of the first portion 231 to other structures (such as the first source 24 of the first thin film transistor 20), and improving the stability of the first thin film transistor 20.

In some embodiments of the present application, the first active layer 21 further includes a first source ohmic contact portion 213 disposed on the other side of the first channel 211. The first thin film transistor 20 further includes a first source 24 integrally formed with the first drain 23. The first source 24 is provided on a surface of a side of the first source ohmic contact portion 213 which is away from the substrate 10, and covers the first source ohmic contact portion 213. Optionally, the edge of the first source 24 protrudes from the edge of the first source ohmic contact portion 213 by 0.5 to 1 microns.

In the display panel provided in the present application, since each first source 24 is integrally formed with a corresponding first drain 23, the production process of the first thin film transistors 20 can be simplified. Further, since the first source 24 is provided on the surface of the side of the first source ohmic contact portion 213 which is away from the substrate 10, and covers the first source ohmic contact portion 213, the first source 24 can protect the first source ohmic contact portion 213, so as to prevent from the damage to the first source ohmic contact portion 213 during the patterning of the film layer in which the first source 24 is located.

In some embodiments of the present application, the display panel further includes a first gate insulating layer 50 disposed on a side of the first active layer 21 which is away from the separation portion 22. The first gate insulating layer 50 includes a first sub-insulating layer 51. The first sub-insulating layer 51 is in contact with the first active layer 21, and the first sub-insulating layer 51 is of a same material as the separation portion 22.

In the display panel provided in the present application, the first channel 211 can be protected by the separation portion 22 covering the first channel 211. Since the first sub-insulating layer 51 is in contact with the first active layer 21, and the first sub-insulating layer 51 is made of the same material as the separation portion 22, the first gate insulating layer 50 can have a good protection function for the first channel 211 while reducing the material cost.

Optionally, the material of both the first sub-insulating layer and the separation portion 22 is silicon oxide, and the hydrogen content in the silicon oxide film layer is lower than that in the silicon nitride film layer.

In some embodiments of the present application, the display panel further includes second thin film transistors 60 disposed on a side of the substrate which faces towards the first thin film transistors 20. Each of the second thin film transistors 60 includes a second active layer 61 disposed on a side of the first active layer 21 which is away from the separation portion 22. The second active layer 61 includes a second channel having a different material from the first channel 211.

In the display panel provided in the present application, since the material of the second channel is different from the material of the first channel 211, the type of the second thin film transistor 60 is different from the type of the first thin film transistor 20, so that the display panel can have two types of thin film transistors, thereby further improving the display performance of the display panel.

In some embodiments of the present application, the second thin film transistors 60 are disposed in the non-display region NAA of the display panel, for example, may be disposed in the gate driving circuit of the non-display region NAA. The second channel is made of low-temperature polysilicon, and a type of the second thin film transistor 60 is a low-temperature polysilicon thin film transistor, thereby enabling the display panel to have advantages such as high mobility, high reaction speed, and the like. In addition, since the type of the second thin film transistor 60 is the low-temperature polysilicon thin film transistor having a high mobility and a high reaction speed, the driving capability of the gate driving circuit is stronger, so that the display panel including the second thin film transistors 60 can have the ability to drive more pixels, the display panel can have a higher resolution, and can apply in the VR/AR display device having a higher resolution requirement. At the same time, since the resolution of the display panel is improved, the number of various types of wiring (such as data lines and scan lines) is increased, and the aperture ratio of the display region AA of the display panel is decreased. In the present application, the first thin film transistors 20 are provided in the display region AA while the second thin film transistors 60 are provided in the non-display region NAA, so that the aperture ratio of the display region AA of the display panel can be improved while the high resolution is ensured.

It should be noted that the second thin film transistors 60 may be provided in the non-display region NAA and/or the display region AA of the display panel. When the second thin film transistors 60 are provided in the non-display region NAA, the type of the display panel may be a liquid crystal display panel. When the second thin film transistors 60 are at least partially provided in the display region AA, the type of the display panel may be an organic light emitting diode display panel.

In some embodiments of the present application, the first gate insulating layer 50 further includes a second sub-insulating layer 52 disposed on a side of the first sub-insulating layer 51 which is away from the first active layer 21, and the second sub-insulating layer 52 and the first sub-insulating layer 51 are different in material. The first thin film transistor 20 includes a first gate 25 disposed on a side of the second sub-insulating layer 52 which is away from the first sub-insulating layer 51. The second thin film transistor 60 further includes a second gate 62 disposed on a side of the second active layer 61 which is away from the substrate 10. The first gate 25 is provided in a same layer as the second gate 62, and the first gate 25 and the second gate 62 are respectively in contact with the second sub-insulating layer 52.

In the display panel provided in the present application, since the first gate 25 and the second gate 62 are provided in the same layer, the number of film layers of the display panel can be reduced, and the manufacturing cost can be reduced.

Further, since the first gate 25 and the second gate 62 are respectively in contact with the second sub-insulating layer 52, and the second sub-insulating layer 52 is different from the first sub-insulating layer 51 in material, the second sub-insulating layer 52 may be provided as a silicon nitride film layer having a higher hydrogen content, thereby facilitating improvement of the performance of the second thin film transistor 60.

In some embodiments of the present application, the display panel further includes a second gate insulating layer 90 disposed on a side of the second active layer 61 which faces towards the second gate 62. The first gate insulating layer 50 disposed between the first active layer 21 and the first gate 25 has a first thickness, the second gate insulating layer 90 disposed between the second active layer 61 and the second gate 62 has a second thickness, and a ratio of the first thickness to the second thickness is less than or equal to 3.

In the display panel provided in the present application, the first thin film transistor 20 is a metal oxide thin film transistor. Therefore, compared with the second thin film transistor 60 the type of which is the low-temperature polysilicon thin film transistor, the mobility is relatively low. In the related art, the performance of the first thin film transistor 20 can be improved by forming a double-gate structure by providing the other gate on the side of the first channel 211 which is away from the first gate 25. However, since the separation layer, the first drain 23, and the first via 40 are provided on the side of the first channel 211 which is away from the first gate 25, the double-gate structure cannot be formed. In order to enable the first thin film transistor 20 to still have a high mobility without having a dual-gate structure, the present application can significantly improve the device performance of the first thin film transistor 20 by making the thickness of the first gate insulating layer 50 provided between the first active layer 21 and the first gate 25 three times or less the thickness of the second gate insulating layer 90 provided between the second active layer 61 and the second gate 62, compared with the related art in which the thickness of the first gate insulating layer 50 provided between the first active layer 21 and the first gate 25 is five times or more the thickness of the second gate insulating layer 90 provided between the second active layer 61 and the second gate 62.

In some embodiments of the present application, the second thin film transistor 60 further includes a second source 63 and a second drain 64. The first thin film transistor 20 further includes a first source conducting portion 70 provided in a same layer as the second source 63 and the second drain 64, and the first source conducting portion 70 is electrically connected to the first source 24 through a second via 80.

In the display panel provided in the present application, since the first source conducting portion 70 electrically connected to the first source 24 is provided in the same layer as the second source 63 and the second drain 64, it is possible to facilitate signal introduction of the first thin film transistor 20, without increasing the number of film layers of the display panel, thereby reducing production and manufacturing costs.

In some embodiments of the present application, the display panel further includes at least one of a composite functional layer 100, an interlayer dielectric layer 110, a first planarization layer 120, a passivation layer 130, a second planarization layer 140, and a common electrode 150. The composite functional layer 100 is disposed between the second active layer 61 and the substrate 10. The composite functional layer 100 includes at least one of a buffer layer and a light shielding layer. The interlayer dielectric layer 110 is disposed on a side of the first drain 23 which is away from the substrate 10. The first planarization layer 120 is disposed on a side, which is away from the substrate 10, of all of the second source 63, the second drain 64, and the first source conducting portion 70. The pixel electrode 30 is disposed on a side of the first planarization layer 120 which is away from the substrate 10, and the first via 40 extends through the interlayer dielectric layer 110 and the first planarization layer 120. The passivation layer 130 is provided on a side of the pixel electrode 30 which is away from the substrate 10. The second planarization layer 140 is disposed on a side of the passivation layer 130 which is away from the substrate 10. The common electrode 150 is disposed on the side of the second planarization layer 140 which is away from the substrate 10.

In a second aspect, the present application provides a method of manufacturing a display panel. The method of manufacturing the display panel includes step S01, step S02, step S03, step S04, step S05, step S06, step S07, step S08, step S09, step S10, and step S11.

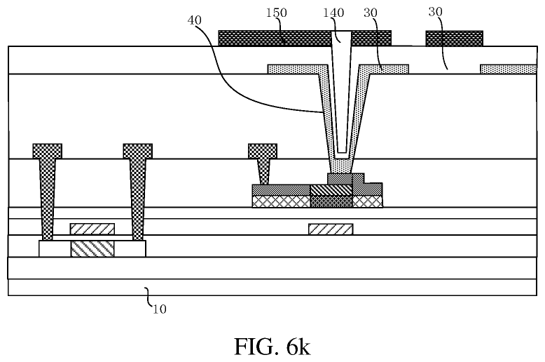

FIG. 6a is a schematic structural diagram of a display panel corresponding to step S01 in a method for manufacturing a display panel according to embodiments of the present application. Referring to FIG. 6a, step S01 includes providing a substrate 10. Alternatively, step S01 further includes forming a composite functional layer 100 on the substrate 10, in which the composite functional layer 100 includes at least one of a buffer layer and a light shielding layer.

FIG. 6b is a schematic structural diagram of a display panel corresponding to step S02 in a method for manufacturing a display panel according to an embodiment of the present application. Referring to FIG. 6b, step S02 includes forming a second active layer 61 of a second thin film transistor on one side of the substrate 10, in which the second active layer 61 includes a second channel and a second source region and a second drain region on both sides of the second channel.

FIG. 6c is a schematic structural diagram of a display panel corresponding to step S03 in a method for manufacturing a display panel according to an embodiment of the present application. Referring to FIG. 6c, step S03 includes forming a second gate insulating layer 90 on the side of the second active layer 61 which is away from the substrate 10, and forming a second gate 62 of the second thin film transistor 60 and a first gate 25 of the first thin film transistor on the side of the second gate insulating layer 90 which is away from the substrate 10.

FIG. 6d is a schematic structural diagram of a display panel corresponding to step S04 in a method for manufacturing a display panel according to an embodiment of the present application. As shown in FIG. 6d, step S04 includes the followings. A first gate insulating layer 50 is formed on the side of the second gate insulating layer 90 which is away from the substrate 10 and covers the first gate 25 and the second gate 62. The first gate insulating layer 50 includes a first sub-insulating layer 51 and a second sub-insulating layer 52. The first sub-insulating layer 51 is provided on the side of the second sub-insulating layer 52 which is away from the substrate 10. The first sub-insulating layer 51 has a hydrogen content lower than that of the second sub-insulating layer 52, and hydrogen activating is performed on the second channel. Thereafter, a first active layer 21 of the first thin film transistor 20 is formed on the side of the first gate insulating layer 50 which is away from the substrate 10. The first active layer 21 includes a first channel 211, and a first source ohmic contact portion and a first drain ohmic contact portion, which are not conductively treated, on both sides of the first channel 211.

FIG. 6e is a schematic structural diagram of a display panel corresponding to step S05 in a method for manufacturing a display panel according to an embodiment of the present application. As shown in FIG. 6e, step S05 includes the followings. A separation layer is formed on a side of the first channel 211 which is away from the substrate 10. The separation layer is made of the same material as the first sub-insulating layer 51, for example, silicon oxide. Then, the separation layer is formed into a separation portion 22 corresponding to the first channel 211 by exposure development and etching. The separation portion 22 has a thickness of 50 -250 nanometers. An included angle a between the side wall 221 of the separation portion 22 and the bottom surface 222 of the separation portion 22 is denoted by a, a range of which is denoted by 30°Sa≤90°. A photoresist is formed on a side of the separation portion 22 which is away from the first channel 211. The exposed and non-conducted first source ohmic contact portion and the first drain ohmic contact portion are conducted by using the separation portion 22 and the photoresist as a mask. The conducting processing includes boron ion doping or argon plasma processing. Thus, the first source ohmic contact portion 213 and the first drain ohmic contact portion 212 are formed. Then, the photoresist is peeled off.

FIG. 6f is a schematic structural diagram of a display panel corresponding to step S06 in a method for manufacturing a display panel according to an embodiment of the present application. As shown in FIG. 6f, step S06 includes the followings. A transparent conductive layer is formed on a side of the separation portion 22 which is away from the substrate 10. The transparent conductive layer is patterned to form a first source 24 and a first drain 23. The first source 24 covers the first source ohmic contact portion 213, and an edge of the first source 24 exceeds beyond an edge of the first source ohmic contact portion 213 by 0.5-1 microns. The first drain 23 includes a first portion 231 and a second portion 232. The second portion 232 of the first drain 23 covers the first drain ohmic contact portion 212, and the edge of the second portion 232 exceeds the edge of the first drain ohmic contact portion 212 by a distance of 0.5-1 microns. And, the edge 223 of the separation portion 22 protrudes from the edge 2311 of the first portion 231 of the first drain 23 by a distance of 1-2 microns.

FIG. 6g is a schematic structural diagram of a display panel corresponding to step S07 in a method for manufacturing a display panel according to an embodiment of the present application. As shown in FIG. 6g, step S07 includes the followings. An interlayer dielectric layer 110 is formed on a side of the transparent conductive layer which is away from the substrate 10. The interlayer dielectric layer 110 is a stack of a silicon nitride film layer, or a silicon oxide film layer; or is a stack of a silicon nitride film layer and a silicon oxide film layer. The interlayer dielectric layer 110 is opened to form a plurality of openings exposing the second source region, the second drain region, and the first source 24. The openings exposing the first sources 24 are second vias 80.

FIG. 6h is a schematic structural diagram of a display panel corresponding to step S08 in a method for manufacturing a display panel according to an embodiment of the present application. As shown in FIG. 6h, step S08 includes the followings. A source-drain metal layer is formed on the side of the interlayer dielectric layer 110 which is away from the substrate 10. The source-drain metal layer may be Ti, Al, Mo or an alloy, and a stack thereof. The source-drain metal layer is patterned to form a second source 63, a second drain 64 and a first source conducting portion 70. The second source 63 is electrically connected to the second source region through an opening exposing the second source region. The second drain 64 is electrically connected to the second drain region through an opening exposing the second drain region. The first source conducting portion 70 is electrically connected to the first source 24 through an opening (the second via 80) exposing the first source 24.

FIG. 6i is a schematic structural diagram of a display panel corresponding to step S09 in a method for manufacturing a display panel according to an embodiment of the present application. As shown in FIG. 6i, step S09 includes the followings. A patterned first planarization layer 120 is formed on one sides, which are away from the substrate 10, of all the second source 63, the second drain 64, and the first source conducting portion 70, by a coating exposure development process. The first planarization layer 120 includes vias corresponding to the first portions 231. Then, the interlayer dielectric layer 110 is etched by using the first planarization layer 120 as a mask. And, vias through the interlayer dielectric layer 110 are formed at positions of the interlayer dielectric layer 110 which are corresponding to the first portions 231. The vias through the interlayer dielectric layer 110 and the vias in the first planarization layer 120 together form first vias 40. Of course, the first vias 40 through the first planarization layer 120 and the interlayer dielectric layer 110 may be formed by one etch by forming a photoresist mask on the first planarization layer 120.

FIG. 6j is a schematic structural diagram of a display panel corresponding to step S10 in a method for manufacturing a display panel according to an embodiment of the present application. As shown in FIG. 6j, step S10 includes the followings. Pixel electrodes 30 are formed on the side of the first planarization layer 120 which is away from the substrate 10. The pixel electrodes 30 are electrically connected to the first portions 231 of the first drains 23 through the first vias 40 respectively.

FIG. 6k is a schematic structural diagram of a display panel corresponding to step S11 in a method for manufacturing a display panel according to an embodiment of the present application. As shown in FIG. 6k, step S11 includes the followings. A passivation layer 130, a common electrode 150, and a second planarization layer 140 are sequentially formed on the side of the pixel electrodes 30 which is away from the substrate 10. The second planarization layer 140 fills grooves formed by the pixel electrodes 30 at the first vias 40.

In summery, a display panel is provided by the present application, and includes a display region. The display panel includes: a substrate; first thin film transistors disposed on one side of the substrate and located in the display region; pixel electrodes, each of the pixel electrodes being disposed on a side of a corresponding one of the first thin film transistors which is away from the substrate and being located in the display region; in which each of the first thin film transistors includes: a first active layer including a first channel and a first drain ohmic contact portion provided on a side of the first channel; a separation portion disposed on a surface of one side of the first channel which is away from the substrate and covering the first channel; a first drain including a transparent first portion disposed on a surface of a side of the separation portion which is away from the first active layer and a transparent second portion disposed on a surface of a side of the first drain ohmic contact portion which is away from the substrate; in which a corresponding one of the pixel electrodes is electrically connected to the first portion through a first via provided on a side of the first portion which is away from the separation portion. The display panel provided in the present application can improve the display image quality of the display panel and reduce the manufacturing cost of the display panel while achieving a high aperture ratio.

The foregoing has described in detail a display panel according to an embodiment of the present application, in which specific examples are used to illustrate the principles and embodiments of the present application. The description of the above embodiments is merely provided to assist in understanding the method of the present application and the core concepts thereof. At the same time, variations will occur to those skilled in the art in both the detailed description and the scope of application in accordance with the teachings of the present application. In view of the foregoing, the present description should not be construed as limiting the application.

1. A display panel comprising a display region, the display panel comprising:
a substrate;
first thin film transistors disposed on one side of the substrate and located in the display region;
pixel electrodes, each of the pixel electrodes being disposed on a side of a corresponding one of the first thin film transistors which is away from the substrate and being located in the display region;
wherein each of the first thin film transistors comprises:
a first active layer comprising a first channel and a first drain ohmic contact portion provided on a side of the first channel;
a separation portion disposed on a surface of one side of the first channel which is away from the substrate and covering the first channel;
a first drain comprising a transparent first portion disposed on a surface of a side of the separation portion which is away from the first active layer, and a transparent second portion disposed on a surface of a side of the first drain ohmic contact portion which is away from the substrate;
wherein a corresponding one of the pixel electrodes is electrically connected to the first portion through a first via provided on a side of the first portion which is away from the separation portion.

2. The display panel according to claim 1, wherein the second portion covers the first drain ohmic contact portion.

3. The display panel according to claim 2, wherein the second portion covers a side wall of the separation portion, and an included angle between the side wall of the separation portion and a bottom surface of the separation portion is denoted by a, a range of which is denoted by 30°≤a≤90°.

4. The display panel according to claim 2, wherein an edge of the separation portion protrudes from an edge of the first portion in a direction in which the separation portion is away from the second portion.

5. The display panel according to claim 4, wherein the first active layer further comprises a first source ohmic contact portion provided on an other side of the first channel,
wherein the first thin film transistor further comprises a first source integrally formed with the first drain, the first source is provided on a surface of a side of the first source ohmic contact portion which is away from the substrate, and covers the first source ohmic contact portion.

6. The display panel according to claim 5, wherein the display panel further comprises a first gate insulating layer disposed on a side of the first active layer which is away from the separation portion, wherein the first gate insulating layer comprises a first sub-insulating layer, the first sub-insulating layer is in contact with the first active layer, and the first sub-insulating layer is of a same material as the separation portion.

7. The display panel according to claim 6, wherein the display panel further comprises second thin film transistors disposed on a side of the substrate which faces towards the first thin film transistors,
wherein each of the second thin film transistor comprises a second active layer disposed on a side of the first active layer which is away from the separation portion, and the second active layer comprises a second channel having a different material from the first channel.

8. The display panel according to claim 7, wherein the first gate insulating layer further comprises a second sub-insulating layer disposed on a side of the first sub-insulating layer which is away from the first active layer, and the second sub-insulating layer and the first sub-insulating layer are different in material;
the first thin film transistor comprises a first gate disposed on a side of the second sub-insulating layer which is away from the first sub-insulating layer; the second thin film transistor further comprises a second gate disposed on a side of the second active layer which is away from the substrate;
wherein the first gate is provided in a same layer as the second gate, and the first gate and the second gate are respectively in contact with the second sub-insulating layer.

9. The display panel according to claim 8, wherein the display panel further comprises a second gate insulating layer disposed on a side of the second active layer which faces towards the second gate, wherein the first gate insulating layer disposed between the first active layer and the first gate has a first thickness, the second gate insulating layer disposed between the second active layer and the second gate has a second thickness, and a ratio of the first thickness to the second thickness is less than or equal to 3.

10. The display panel according to claim 7, wherein the second thin film transistor further comprises a second source and a second drain, the display panel further comprises a first source conducting portion provided in a same layer as the second source and the second drain, and the first source conducting portion is electrically connected to the first source through a second via.

11. The display panel according to claim 1, wherein a vertical projection of the first via on the first active layer overlaps the first channel.

12. The display panel according to claim 11, wherein the second portion covers the first drain ohmic contact portion.

13. The display panel according to claim 12, wherein the second portion covers a side wall of the separation portion, and an included angle between the side wall of the separation portion and a bottom surface of the separation portion is denoted by a, a range of which is denoted by 30°≤a≤90°.

14. The display panel according to claim 12, wherein an edge of the separation portion protrudes from an edge of the first portion in a direction in which the separation portion is away from the second portion.

15. The display panel according to claim 14, wherein the first active layer further comprises a first source ohmic contact portion provided on an other side of the first channel,
wherein the first thin film transistor further comprises a first source integrally formed with the first drain, the first source is provided on a surface of a side of the first source ohmic contact portion which is away from the substrate, and covers the first source ohmic contact portion.

16. The display panel according to claim 15, wherein the display panel further comprises a first gate insulating layer disposed on a side of the first active layer which is away from the separation portion, wherein the first gate insulating layer comprises a first sub-insulating layer, the first sub-insulating layer is in contact with the first active layer, and the first sub-insulating layer is of a same material as the separation portion.

17. The display panel according to claim 16, wherein the display panel further comprises second thin film transistors disposed on a side of the substrate which faces towards the first thin film transistors,
wherein each of the second thin film transistor comprises a second active layer disposed on a side of the first active layer which is away from the separation portion, and the second active layer comprises a second channel having a different material from the first channel.

18. The display panel according to claim 17, wherein the first gate insulating layer further comprises a second sub-insulating layer disposed on a side of the first sub-insulating layer which is away from the first active layer, and the second sub-insulating layer and the first sub-insulating layer are different in material;
the first thin film transistor comprises a first gate disposed on a side of the second sub-insulating layer which is away from the first sub-insulating layer; the second thin film transistor further comprises a second gate disposed on a side of the second active layer which is away from the substrate;
wherein the first gate is provided in a same layer as the second gate, and the first gate and the second gate are respectively in contact with the second sub-insulating layer.

19. The display panel according to claim 18, wherein the display panel further comprises a second gate insulating layer disposed on a side of the second active layer which faces towards the second gate, wherein the first gate insulating layer disposed between the first active layer and the first gate has a first thickness, the second gate insulating layer disposed between the second active layer and the second gate has a second thickness, and a ratio of the first thickness to the second thickness is less than or equal to 3.

20. The display panel according to claim 17, wherein the second thin film transistor further comprises a second source and a second drain, the display panel further comprises a first source conducting portion provided in a same layer as the second source and the second drain, and the first source conducting portion is electrically connected to the first source through a second via.
